(19) United States
(12) Patent Application Publication
(10) Pub. No.: US 2016/0118965 A1
(43) Pub. Date: Apr. 28, 2016

(54) SEMICONDUCTOR DEVICE

(71) Applicants: Takayuki FUJIAWARA, Tokyo (JP); PS4 LUXCO S.A.R.L., Luxembourg (LU)

(72) Inventor: Takayuki Fujiawara, Tokyo (JP)

(21) Appl. No.: 14/892,994

(22) PCT Filed: May 20, 2014
(86) PCT No.: PCT/JP2014/063360

§ 371 Date: Nov. 20, 2015

(30) Foreign Application Priority Data
May 23, 2013 (JP) 2013-108581

(51) Int. Cl. H03K 5/02

(52) U.S. Cl. CPC H03K 5/023

(57) ABSTRACT

The present disclosure relates to a semiconductor device. In one embodiment, the semiconductor device includes first and second input terminals, a first transistor a control terminal of which is connected to the first input terminal, a second transistor a control terminal of which is connected to the second input terminal, third and fourth transistors which are connected respectively to the first and second transistors, and control terminals of which are connected to one another at a first node, a fifth transistor a control terminal of which is connected to the first input terminal, a sixth transistor a control terminal of which is connected to the second input terminal, seventh and eighth transistors which are connected respectively to the fifth and sixth transistors, and control terminals of which are connected to one another at a second node, and a switch connected between the first node and the second node.

### TECHNICAL FIELD

### Notice Regarding Related Application

The present invention is based upon the priority claim of Japanese patent application No. 2013-108581 (filed on May 23, 2013), the disclosure of which is incorporated herein in its entirety by reference thereto.

The present invention relates to a semiconductor device, and in particular relates to a technique for configuring an input circuit in a semiconductor device.

### BACKGROUND ART

Various input circuits for semiconductor devices are known.

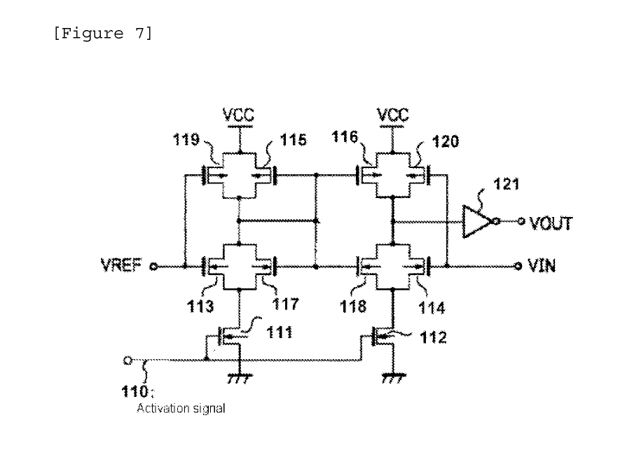

For example, patent literature article 1 discloses an input receiver circuit for transferring a signal, input from the outside of a semiconductor memory device or the like, to the inside of the semiconductor memory device (see FIG. 7). In the input receiver circuit, n-channel MOS transistors 117 and 118 are provided in parallel with n-channel MOS transistors 113 and 114, and p-channel MOS transistors 119 and 120 are provided in parallel with p-channel MOS transistors 115 and 116. An input signal (VIN) is amplified not only by the n-channel MOS transistor 114, but also in a supplementary manner by the p-channel MOS transistor 120, thereby maintaining the gain if a reference voltage (VREF) is minimal, and also suppressing amplification effects of the reference voltage itself. Such an input receiver circuit is known as a QCR (Quad Couple Receiver) circuit. It should be noted that n-channel MOS transistors 111 and 112 activate the QCR circuit when an activation signal 110 is at the H level. Further, an inverter circuit 121 outputs a signal output VOUT, which is the inverse of a drain signal from the n-channel MOS transistor 114.

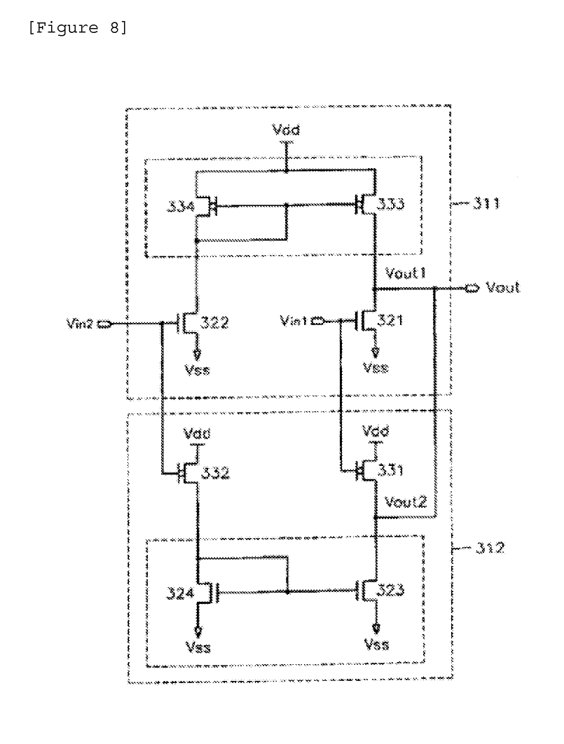

Further, patent literature article 2 discloses a complementary differential input buffer of a semiconductor memory device (see FIG. 8). The input buffer is equipped with: a first differential amplifier portion 311 which is provided with a first MOS transistor 321 into which a first external signal Vin1 is input, and a second MOS transistor 322 into which a second external signal Vin2 is input, wherein said first differential amplifier portion 311 amplifies the voltage difference between the first and second external signals Vin1 and Vin2 and outputs said voltage difference as a first intermediate output Vout1; and a second differential amplifier portion 312 which is provided with a third MOS transistor 331 into which the first external signal Vin1 is input, and a fourth MOS transistor 322 into which the second external signal is input, wherein said second differential amplifier portion 312 amplifies the voltage difference between the first and second external signals Vin1 and Vin2 and outputs said voltage difference as a second intermediate output Vout2; and the first intermediate output Vout1 from the first differential amplifier portion 311 and the second intermediate output Vout2 from the second differential amplifier portion 312 are combined and output as a single output signal. It should be noted that MOS transistors 333 and 334 form a current mirror circuit which acts as a load for the first MOS transistor 321 and the second MOS transistor 322. Further, MOS transistors 323 and 324 form a current mirror circuit which acts as a load for the third MOS transistor 331 and the fourth MOS transistor 332. Such an input buffer is known as a CMA (Current Mirror Amplifier) circuit.

### PRIOR ART LITERATURE

### Patent literature

Patent literature article 1: Japanese Patent Kokai 1999-266152

Patent literature article 2: Japanese Patent Kokai 2000-306385

### SUMMARY OF THE INVENTION

The following analysis is provided in the present invention.

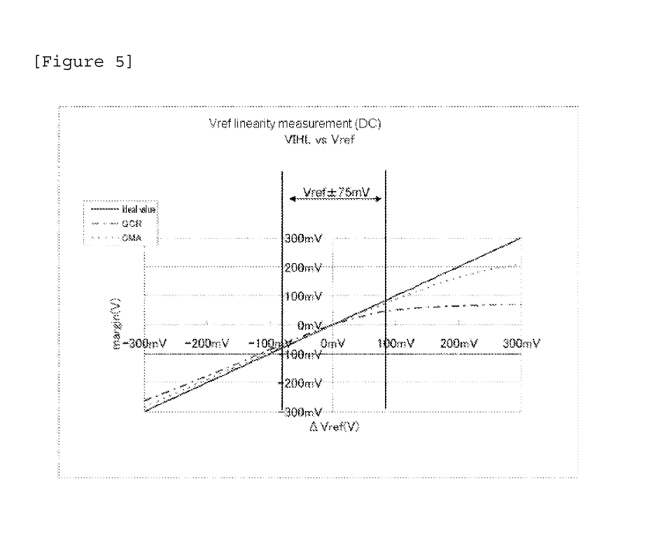

Here, the characteristics of the QCR circuit disclosed in patent literature article 1 and the CMA circuit disclosed in patent literature article 2 will be described. FIG. 5 is a chart illustrating the ability of the QCR circuit and the CMA circuit to track the input signals (VIN in FIG. 7 and Vin1 in FIG. 8) and the reference voltages (VREF in FIG. 7 and Vin2 in FIG. 8). In FIG. 5, the horizontal axis represents an amount of change ΔVref in the reference voltage Vref, and the vertical axis represents an amount of change, ‘margin’, from a threshold (VIHL) at which the input signal is recognized as a logical high level.

As illustrated in FIG. 5, the QCR circuit is provided with a characteristic whereby, even if a reference potential supplied to one input terminal changes, the threshold of the input circuit does not readily change. Meanwhile, in contrast to the QCR circuit, the CMA circuit is provided with a characteristic whereby if the reference voltage supplied to one input terminal changes, the threshold of the input circuit tracks the change in the reference voltage.

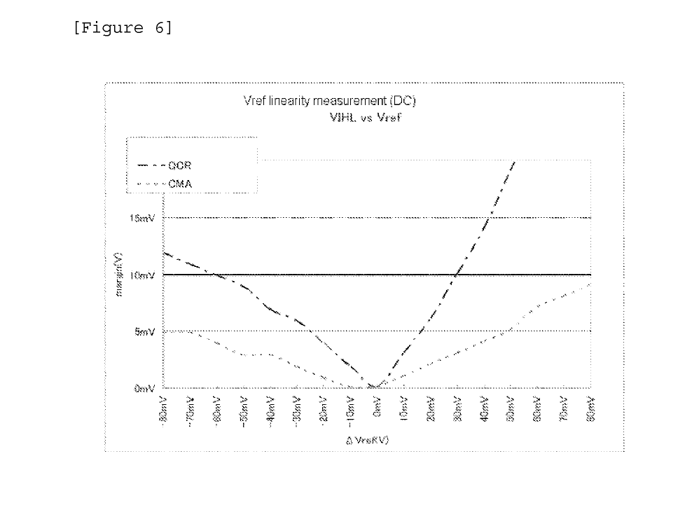

FIG. 6 is a chart in which the tracking errors in the central portion of FIG. 5 are represented using absolute values. As illustrated in FIG. 6, from the viewpoint of the tracking error relative to the reference voltage, the QCR circuit has a larger tracking error than the CMA circuit.

Now, semiconductor devices provided with input circuits are used in various devices such as personal computers, servers, and mobile telephones, and many suppliers which supply these end products to the market exist as users of semiconductor devices. Certain users require input circuits having a characteristic in which the threshold does not vary readily in response to changes in the reference potential, while other users require input circuits having a characteristic in which the threshold tracks changes in the reference potential. There are thus cases in which the characteristics required of the input circuit differ depending on the user.

In such cases, individual chips must be designed and manufactured in response to the different requirements for each user, leading to significant increases in the cost of manufacturing the semiconductor device.

A semiconductor device according to one aspect of the present invention comprises: first and second input terminals; a first transistor a control terminal of which is connected to the first input terminal; a second transistor a control terminal of which is connected to the second input terminal; third and fourth transistors which are connected respectively to the first and second transistors, and control terminals of which are connected to one another at a first node; a fifth transistor a control terminal of which is connected to the first input terminal; a sixth transistor a control terminal of which is connected to the second input terminal; seventh and eighth transistors which are connected respectively to the fifth and sixth transistors, and control terminals of which are connected to one another at a second node; and a switch connected between the first node and the second node.

According to the present invention, it is possible to achieve a highly versatile input circuit having a simple configuration.

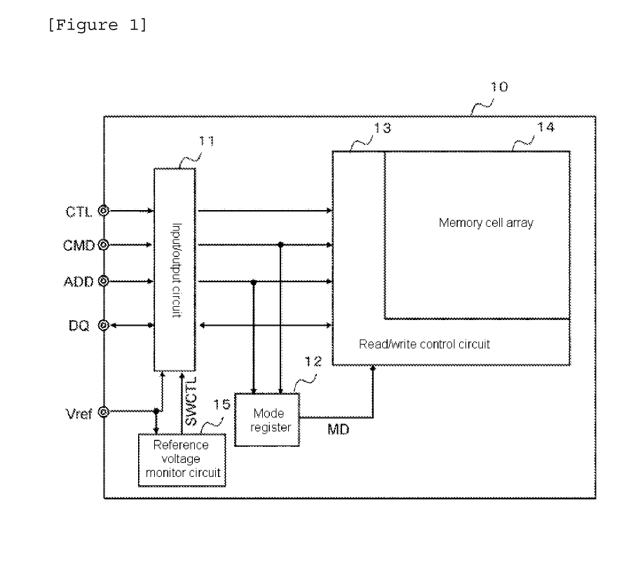

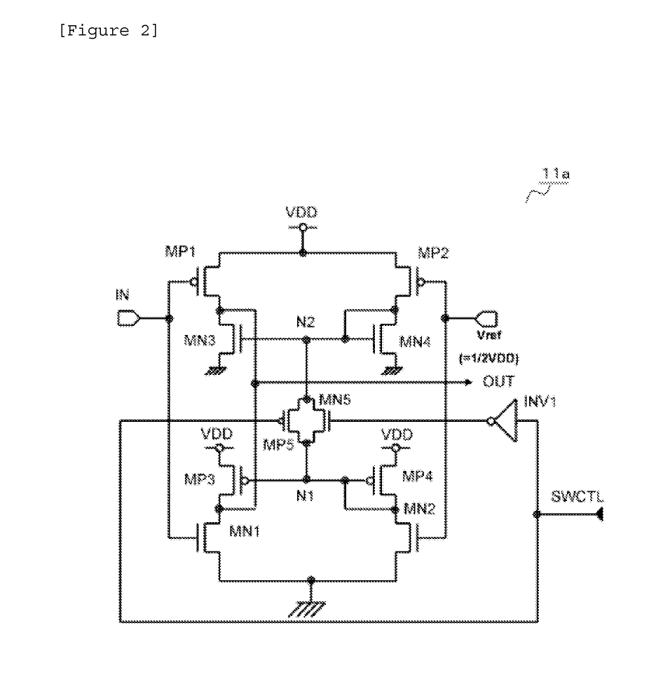

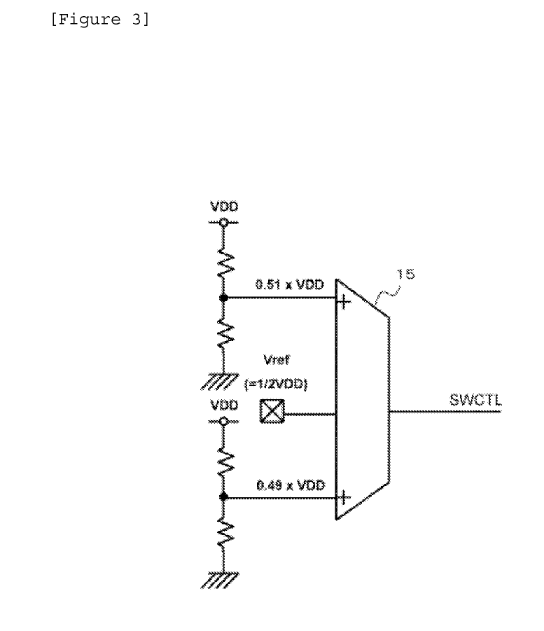

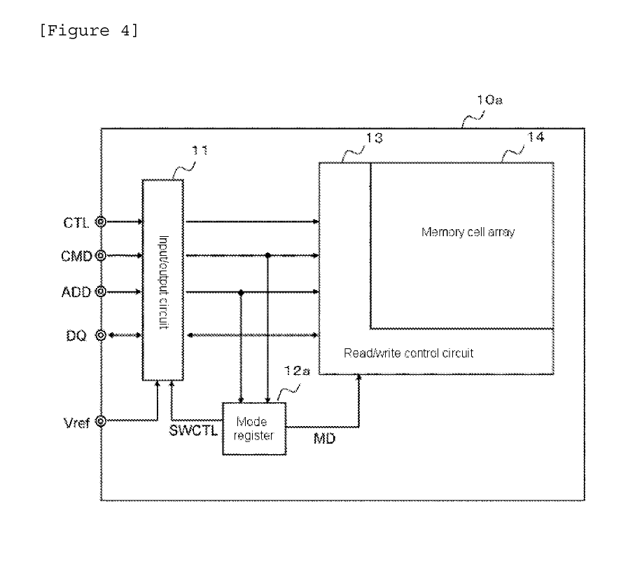

### BRIEF DESCRIPTION OF THE DRAWINGS

[FIG. 1] is a block diagram illustrating the configuration of a semiconductor device according to a first exemplary embodiment.

[FIG. 2] is a circuit diagram of an input circuit according to the first exemplary embodiment.

[FIG. 3] is a block diagram illustrating the configuration of a reference voltage monitor circuit.

[FIG. 4] is a block diagram illustrating the configuration of a semiconductor device according to a second exemplary embodiment.

[FIG. 5] is a chart illustrating the ability of a QCR circuit and a CMA circuit to track input signals and reference voltages.

[FIG. 6] is a chart in which tracking errors in the central portion of FIG. 5 are represented using absolute values.

[FIG. 7] is a circuit diagram of an input receiver circuit described in patent literature article 1.

[FIG. 8] is a circuit diagram of an input buffer described in patent literature article 2.

### DETAILED DESCRIPTION

Modes of embodying the present invention will now be described briefly. It should be noted that drawing reference codes assigned in the following overview are shown by way of example solely in order to aid understanding of the invention, and the present invention is not intended to be limited to the modes illustrated in the drawings.

A semiconductor device according to one mode of embodiment comprises: first and second input terminals (IN and Vref in FIG. 2); a first transistor (MN1 in FIG. 2) a control terminal of which is connected to the first input terminal; a second transistor (MN2 in FIG. 2) a control terminal of which is connected to the second input terminal; third and fourth transistors (MP3 and MP4 in FIG. 2) which are connected respectively to the first and second transistors, and control terminals of which are connected to one another at a first node (N1 in FIG. 2); a fifth transistor (MP1 in FIG. 2) a control terminal of which is connected to the first input terminal; a sixth transistor (MP2 in FIG. 2) a control terminal of which is connected to the second input terminal; seventh and eighth transistors (MN3 and 4 in FIG. 2) which are connected respectively to the fifth and sixth transistors, and control terminals of which are connected to one another at a second node (N2 in FIG. 2); and a switch (MP5 and/or MN5 in FIG. 2) connected between the first node and the second node.

When such a semiconductor device is employed, an input circuit acting as a QCR circuit is formed when the switch is short-circuited, and an input circuit acting as a CMA circuit is formed when the switch is open. It is therefore possible to achieve a highly versatile input circuit having a simple configuration.

The semiconductor device may additionally be provided with a detecting circuit (corresponding to 15 in FIG. 1) which detects the potential at the second input terminal, and which turns the switch off if the potential is within a prescribed range, and turns the switch on if the potential is outside said prescribed range.

In the semiconductor device, the prescribed range may include an intermediate value between the voltages of the first and second power sources.

The semiconductor device may additionally be provided with a register (12a in FIG. 4) which sets an operating mode, and the switch may be turned on when the register is set to a prescribed mode.

A detailed description will now be provided in the context of exemplary embodiments, with reference to the drawings.

### Exemplary Embodiment 1

FIG. 1 is a block diagram illustrating the configuration of a semiconductor device according to the first exemplary embodiment. In FIG. 1, a semiconductor device 10 is a memory such as a DRAM (Dynamic Random Access Memory), provided with an input/output circuit 11, a mode register 12, a read/write control circuit 13, a memory cell array 14 and a reference voltage monitor circuit 15.

The input/output circuit 11 functions as an input circuit which accepts as inputs, from the outside, a control signal CTL, a command signal CMD, an address signal ADD and a data signal DQ, and buffers and binarizes said signals, and outputs them to the mode register 12 and the read/write control circuit 13. Further, the input/output circuit 11 accepts the reference voltage Vref as an input from the outside, and binarizes the input signals in accordance with whether the voltage level of the input signal is higher or lower than the reference voltage Vref. Further, the input/output circuit 11 accepts as an input a selection signal SWCTL from the reference voltage monitor circuit 15, and switches the operation of the input circuit in accordance with the selection signal SWCTL.

Further, the input/output circuit 11 functions as an output circuit which buffers a data signal output from the read/write control circuit 13, and outputs said data signal to the outside as a data signal DQ.

The mode register 12 is a register which sets an operating mode, and which outputs to the read/write control circuit 13 a mode signal MD created on the basis of the command signal CMD and the address signal ADD.

The read/write control circuit 13 performs control in such a way that if the mode signal MD indicates a write mode, the data signal DQ input from the outside is written to a cell in the memory cell array 14, specified by the address signal ADD. Control is also performed in such a way that if the mode signal MD indicates a read mode, the data signal read from a cell in the memory cell array 14, specified by the address signal ADD, is read to the outside as the data signal DQ.

The reference voltage monitor circuit 15 functions as a detecting circuit into which the reference voltage Vref is input from the outside, and which outputs the selection signal SWCTL having a logical value which depends on whether or not the reference voltage Vref is contained in a prescribed range.

FIG. 2 is a circuit diagram of the input circuit according to the first exemplary embodiment. The input circuit 11a illustrated in FIG. 2 corresponds to one input circuit in the input/output circuit 11 in FIG. 1. The input circuit 11a in FIG. 2 is provided with NMOS transistors MN1 to MN5, PMOS transistors MP1 to MP5, and an inverter circuit INV1.

In the NMOS transistor MN1, the drain is connected to the drain of the PMOS transistor MP1, the drain of the NMOS transistor MN3 and the drain of the PMOS transistor MP3, the gate accepts the input signal IN, and the source is grounded.

In the NMOS transistor MN2, the drain is connected to the drain and the gate of the PMOS transistor MP4, and to the node N1, the gate accepts the reference voltage Vref, and the source is grounded.

In the PMOS transistor MP1, an output signal OUT is output from the drain, the gate accepts the input signal IN, and the source is connected to the power source VDD.

In the PMOS transistor MP2, the drain is connected to the drain and the gate of the NMOS transistor MN4, and to the node N2, the gate accepts the reference voltage Vref, and the source is connected to the power source VDD.

In the NMOS transistor MN3, the gate is connected to the node N2, and the source is grounded.

In the NMOS transistor MN4, the source is grounded.

In the PMOS transistor MP3, the gate is connected to the node N1, and the source is connected to the power source VDD.

In the PMOS transistor MP4, the source is connected to the power source VDD.

In the NMOS transistor MN5, one of the drain and the source is connected to the node N1, the other of the drain and the source is connected to the node N2, and the gate is connected to the output from the inverter circuit INV1 which logically inverts the selection signal SWCTL.

In the PMOS transistor MP5, one of the drain and the source is connected to the node N1, the other of the drain and the source is connected to the node N2, and the gate accepts the selection signal SWCTL. The PMOS transistor MP5 together with the NMOS transistor MN5 form a transfer gate which functions as a switch.

In the input circuit 11a configured as described hereinabove, if the selection signal SWCTL is at the L level, then the NMOS transistor MN5 and the PMOS transistor MP5 are on, and the nodes N1 and N2 are short-circuited to one another. The input circuit 11a in FIG. therefore acts as a QCR circuit. In other words, the transistors MN1 to MN4 and MP1 to MP4 in FIG. 2 correspond respectively to the transistors 114, 113, 118, 117, 120, 119, 116 and 115 in FIG. 7.

Meanwhile, if the selection signal SWCTL is at the H level, then the NMOS transistor MN5 and the PMOS transistor MP5 are off, and the path between the nodes N1 and N2 is in an open state. The input circuit 11a in FIG. 2 therefore acts as a CMA circuit. In other words, the transistors MN1 to MN4 and MP1 to MP4 in FIG. 2 correspond respectively to the transistors 321 to 324 and 331 to 334 in FIG. 8.

As described hereinabove, the input circuit 11a becomes a QCR circuit simply by turning on the switch added to the CMA circuit. It is therefore possible to achieve an input circuit having a simple configuration.

The reference voltage monitor circuit 15 will now be described. FIG. 3 is a block diagram illustrating the configuration of the reference voltage monitor circuit 15. In FIG. 3, the reference voltage monitor circuit 15 accepts as inputs the reference voltage Vref, 0.51×VDD, which is 0.51 times the voltage of the power source VDD, and 0.49×VDD, which is 0.49 times the voltage of the power source VDD.

If 0.51×VDD>Vref>0.49×VDD, the reference voltage monitor circuit 15 outputs the H level as the selection signal SWCTL. In this case, the input circuit 11a in FIG. 2 operates as a CMA circuit.

Further, if 0.51×VDD<Vref or Vref<0.49×VDD, the reference voltage monitor circuit 15 outputs the L level as the selection signal SWCTL. In this case, the input circuit 11a in FIG. 2 operates as a QCR circuit.

More specifically, FIG. 6 presents a plot of the difference between ΔVref in FIG. 5 and the ideal values in a QCR circuit and a CMA circuit respectively, shown as absolute values, in an extract over a range of ±10% of Vref, where Vref is taken to be 0.75 V (VDD=1.5 V), in other words a range in which ΔVref is −75 mV to +75 mV. Here, in FIG. 6 it can be seen that, if the user has imposed a specification “Vref ±10%, within a threshold Vref tracking error of 10 mV”, as indicated by the dashed line SP, the threshold Vref tracking error 10 mV is exceeded in the case of the QCR circuit, and this is outside the specification. Meanwhile, the characteristic remains within the specification in the case of a CMA circuit.

Therefore in order to satisfy the specification, the input circuit should be operated as a CMA circuit for Vref ±10%. Further, in the range outside Vref ±10%, (the range in which the user has not imposed a standard), the input circuit should be operated as a QCR circuit in order for the semiconductor device to operate more stably.

According to the semiconductor device in the first exemplary embodiment, it is possible to set whether the input circuit 11a is to act as a CMA circuit or as a QCR circuit, in accordance with whether or not the reference voltage Vref is included in a prescribed range. It should be noted that the prescribed range preferably includes 0.5×VDD. Further, the prescribed range described hereinabove is 0.51×VDD to 0.49×VDD, but these numerical values are examples, and are not restrictive. Exemplary embodiment 2

FIG. 4 is a block diagram illustrating the configuration of a semiconductor device according to the second exemplary embodiment. In FIG. 4, the same reference codes as in FIG. 1 represent the same objects, and descriptions thereof are omitted. In the semiconductor device 10a in FIG. 4, the reference voltage monitor circuit 15 in FIG. 1 has been removed, and a mode register 12a has been provided instead of the mode register 12 in FIG. 1.

In addition to the functions of the mode register 12 in FIG. 1, the mode register 12a also has an input circuit selecting mode which sets the selection signal SWCTL to the H or L level on the basis of the command signal CMD and the address signal ADD.

According to the semiconductor device in the second exemplary embodiment, it is possible to select whether the input circuit 11a is to act as a QCR circuit or as a CMA circuit, depending on the setting of the input circuit selecting mode in the mode register 12a.

It should be noted that the disclosures in the abovementioned patent literature are incorporated herein by reference. Within the framework of the entire disclosure of the present invention (including the scope of the claims), and on the basis of its basic technical concepts, modifications and adjustments may be made to the modes of embodying the invention and to exemplary embodiments thereof. Further, various combinations of or selections from the various disclosed elements (including for example each element of each claim, each element of each exemplary embodiment, and each element of each drawing) are possible within the framework of the entire disclose of the present invention. In other words, it goes without saying that the present invention includes various variations and modifications that could be arrived at by one skilled in the art in accordance with the entire disclosure and technical concepts therein, including the scope of the claims. In particular, with regard to ranges of numerical values set forth herein, arbitrary numerical values or sub-ranges contained within said ranges should be interpreted as being specifically set forth, even if not otherwise set forth.

### EXPLANATION OF THE REFERENCE CODES

10, 10a Semiconductor device

11 Input/output circuit

11a Input circuit

12, 12a Mode register

13 Read/write control circuit

14 Memory cell array

15 Reference voltage monitor circuit

INV1 Inverter circuit

MN1 to MN5 NMOS transistor

MP1 to MP5 PMOS transistor

1. A semiconductor device comprising:
first and second input terminals;
a first transistor a control terminal of which is connected to the first input terminal;
a second transistor a control terminal of which is connected to the second input terminal;
third and fourth transistors which are connected respectively to the first and second transistors, and control terminals of which are connected to one another at a first node;
a fifth transistor a control terminal of which is connected to the first input terminal;
a sixth transistor a control terminal of which is connected to the second input terminal;
seventh and eighth transistors which are connected respectively to the fifth and sixth transistors, and control terminals of which are connected to one another at a second node; and
a switch connected between the first node and the second node.

2. The semiconductor device as claimed in claim 1, wherein:
first and second power sources are additionally provided, and
the first and third transistors are connected in series between the first and second power sources, the second and fourth transistors are connected in series between the first and second power sources, the fifth and seventh transistors are connected in series between the first and second power sources, and the sixth and eighth transistors are connected in series between the first and second power sources.

3. The semiconductor device as claimed in claim 2, wherein the first and third transistors are connected to one another at a third node, and the fifth and seventh transistors are connected to one another at a fourth node which is connected to the third node.

4. The semiconductor device as claimed in claim 3, wherein the second and third transistors are connected to one another at a fifth node which is connected to the first node, and the sixth and eighth transistors are connected to one another at a sixth node which is connected to the second node.

5. The semiconductor device as claimed in claim 1, wherein the first, second, seventh and eighth transistors are of a first conductor type, and the third, fourth, fifth and sixth transistors are of a second conductor type which is different from the first conductor type.

6. The semiconductor device as claimed in claim 1, further comprising a detecting circuit which detects the potential at the second input terminal, and which turns the switch off when the potential is within a prescribed range, and turns the switch on when the potential is outside said prescribed range.

7. The semiconductor device as claimed in claim 6, wherein the prescribed range includes an intermediate value between the voltages of the first and second power sources.

8. The semiconductor device as claimed in claim 1, further comprising a register which sets an operating mode, and in that the switch is turned on when the register is set to a prescribed mode.
